(19) United States
(12) Patent Application Publication
(10) Pub. No.: US 2009/0237164 A1
(43) Pub. Date: Sep. 24, 2009

(54) LOW LEAKAGE CURRENT AMPLIFIER

(76) Inventors: Kiyoshi Kase, Austin, TX (US); Dzung T. Tran, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 12/053,754

(22) Filed: Mar. 24, 2008

(51) Int. Cl. H03F 3/45

(52) U.S. Cl. 330/253

(57) ABSTRACT

A circuit includes first, second, and third inverters and first and second transistors. The first inverter has an input, an output, a first supply terminal, and a second supply terminal. The second inverter has an input, an output, a first supply terminal, and a second supply terminal. The first transistor has a first current electrode for receiving a first supply voltage, a control electrode coupled to the output of the first inverter, and a second current electrode coupled to the first supply terminals of both the first and second inverters. The second transistor has a first current electrode coupled to the second supply terminals of the first and second inverters, a control electrode coupled to the output of the first inverter, and a second current electrode for receiving a second supply voltage. The third inverter has an input coupled to the output of the second inverter, and an output coupled to the output of the first inverter.

### FIELD OF THE INVENTION

The present invention relates generally to semiconductors, and more particularly to amplifier circuits that compensate current leakage.

### BACKGROUND OF THE INVENTION

Semiconductor circuits, regardless of the process used in manufacturing, exhibit a variation in their operating characteristics as a result of processing, voltage and temperature (PVT) variations. For example, within a same manufacturing process all of the transistors are not manufactured with precisely the same physical characteristics. Any variation results in a difference in the operating performance of the circuit. Additionally, the temperature that exists at each junction of n-type and p-type material directly affects the performance of the device associated with that junction. Such variations create a number of serious operational issues. Due to varied operating conditions, the propagation delay and the output impedance of amplifiers varies widely. Propagation delay is the amount of time it takes for a transistor to switch state once a control signal is applied to make the transistor switch. When a differential amplifier is used a common mode voltage is selected as a reference voltage for one of the two input signal. The output logic state of the amplifier is determined by a value of the other input signal relative to the common mode voltage. For low power supply voltage systems operating at high frequencies, the other input signal does not typically obtain a value that adequately turns off transistors. The partial conduction of transistors in an amplifier results in one or more current paths existing between a power supply voltage terminal and a ground terminal that are not intended to exist. Such current paths result in undesired leakage paths for current to flow and undesirably use power. Leakage current paths are particularly problematic for electronic products that use batteries.

### BRIEF DESCRIPTION OF THE DRAWINGS

The present invention is illustrated by way of example and not limitation in the accompanying figures, in which like references indicate similar elements, and in which:

FIG. 1 illustrates in schematic diagram form an amplifier circuit in accordance with one form of the present invention;

FIG. 2 illustrates in schematic diagram form an amplifier in accordance with another form of the present invention;

FIG. 3 illustrates in schematic diagram form an amplifier in accordance with a further form of the present invention;

FIG. 4 illustrates in schematic diagram form an amplifier in accordance with yet another form of the present invention; and

FIG. 5 illustrates in graphical form voltage/current waveforms associated with the amplifier embodiments described herein relative to conventional amplifier performance.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

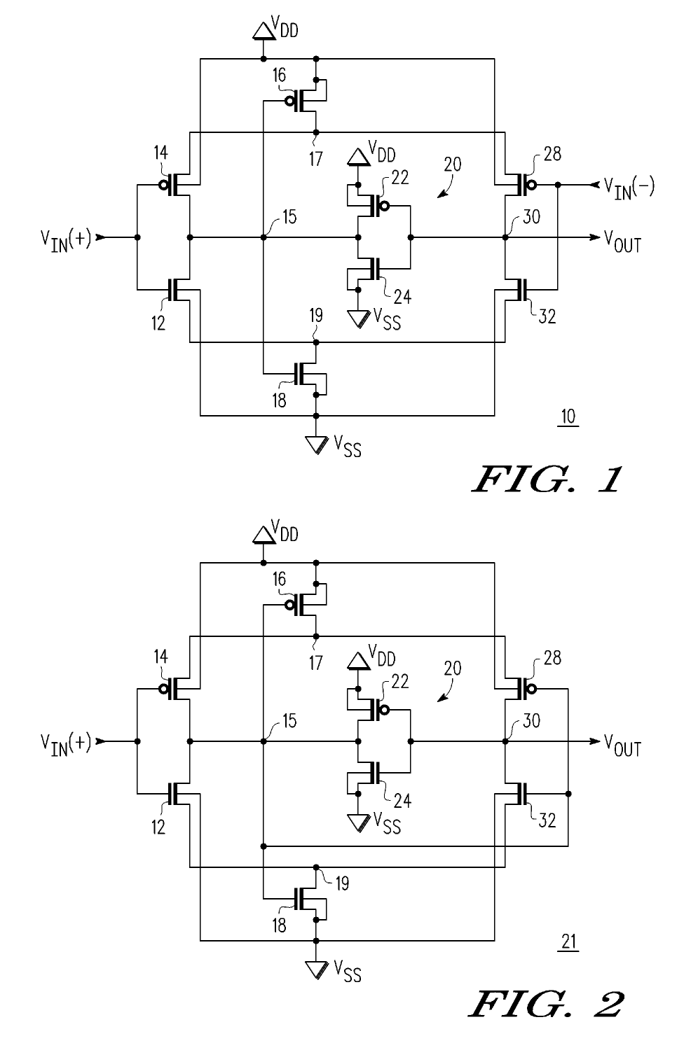

FIG. 1 illustrates an amplifier circuit 10 that has a differential input for receiving two input voltages defined by the voltages V_{IN}(+) and V_{IN}(−) and has a single output that provides the output voltage V_{OUT}. In one form the two input voltages form a differential signal in which each voltage is different in value. In another form the signal V_{IN}(+) of the two signals is an input logic signal and the signal V_{IN}(−) of the two signals is a reference voltage. It should be understood that the plus and minus signs associated with these two voltages do not necessarily imply that one is a positive voltage and the other is a negative voltage. In many applications both voltages have a same polarity while having a different value. An N-channel transistor 12 has a gate or control electrode connected to a gate of a P-channel transistor 14 for receiving the input voltage V_{IN}(+). A source of transistor 12 is connected to a node 19 and a drain of transistor 12 is connected to a node 15 and to a drain of transistor 14. A source of transistor 14 is connected to a node 17. Transistor 12 has a substrate or bulk that is connected to a power supply voltage terminal labeled V_{SS}. In one form the power supply voltage terminal V_{SS} is an earth ground terminal. Transistor 14 has a substrate or bulk that is connected to a power supply voltage terminal labeled V_{DD}. A P-channel transistor 16 has a source and a substrate thereof connected to the V_{DD} power supply voltage terminal. A gate of transistor 16 is connected to node 15, and a drain of transistor 16 is connected to node 17. An N-channel transistor 18 has a drain connected to a node 19 and a gate connected to the gate of transistor 16 at node 15. A source of transistor 18 is connected to a substrate thereof and to the V_{SS} power supply voltage terminal. An inverter 20 has an output thereof connected to node 15 and an input thereof connected to a node 30. A P-channel transistor 22 has a source connected to a substrate thereof and to the V_{DD} power supply voltage terminal. Transistor 22 has a gate connected to a gate of an N-channel transistor 24 at node 30. Transistor 22 also has a drain connected to a drain of transistor 24 at node 15. A source of transistor 24 is connected to a substrate thereof and to the V_{SS} power supply voltage terminal. A P-channel transistor 28 has a source connected to node 17, a gate connected to a terminal for receiving the input voltage V_{IN}(−) and to a substrate thereof, and has a drain connected to node 30 that provides an output voltage signal labeled V_{OUT}. Transistor 28 has a substrate connected to the power supply voltage V_{DD}. An N-channel transistor 32 has a drain connected to node 30, a gate connected to the gate of transistor 28 for receiving the V_{IN}(−) input voltage, and a source connected to node 19. The substrate of transistor 32 is connected to the V_{SS} power supply voltage terminal.

In operation, the inverter 20 functions to remove a floating voltage state that can otherwise exist at node 15. Amplifier circuit 10 functions as a differential amplifier to amplify a difference between the input voltages V_{IN}(−) and V_{IN}(+). Assume in one form that V_{DD} is a positive power supply voltage and that V_{SS} is an earth ground. In many product applications, such as battery-powered wireless devices, the value of V_{DD} is approximately one volt. The voltage V_{IN}(−) functions as a reference voltage. The value of V_{OUT} therefore is determined to be a logic high or logic low value depending upon whether the other input, V_{IN}(+), is above or below the reference voltage. In a differential amplifier the desired value for the reference voltage V_{IN}(−) is a common mode voltage value that is one-half of the value of V_{DD}. The one-half value permits as much voltage swing above the reference point as below it and is thus symmetric. However, when V_{DD} is a small value, such as one volt, there is typically no more than one-half volt between the reference voltage or trip point and the maximum or minimum voltage. With propagation delays and high switching frequencies the voltages applied to the gates of the transistors are not typically high enough or low enough to fully turn off the transistors. As a result, leakage currents may develop in amplifier circuit 10. For example, transistors 12 and 14 function as an inverter. When V_{IN}(+) is near ground or V_{SS}, node 15 is pulled to V_{DD} by transistor 14 via transistor 16. Transistor 12 is non-conductive to reinforce node 15 having a high voltage. However, as the voltage at node 15 increases, node 15 operates to start to bias transistor 16 off and prevent node 15 from reaching the V_{DD} power supply voltage potential. The inability of node 15 from reaching the full V_{DD} power supply voltage potential results in transistor 16 being partially conductive rather than being fully turned off. The partial conduction of transistor 16 and the resulting conduction of transistor 18 from the higher voltage at node 15 results in a leakage current being conducted by transistors 16 and 18 from V_{DD} to V_{SS}. To prevent this unwanted power dissipation, the inverter 20 is provided to fully pull node 15 up to the full V_{DD} voltage potential. Inverter 20 uses the voltage at node 30 as an input to determine whether to connect the V_{DD} or the V_{SS} supply voltages to node 15. Transistors 28 and 32 function as an inverter that responds to the bias from V_{IN}(−) to provide a voltage at node 30. When V_{IN}(−) assumes a reference voltage value that is the common mode voltage of one-half the value of V_{DD}, initially both of transistors 28 and 32 are partially conductive. The increase in voltage at node 15 from the low value of V_{IN}(+) causes transistor 18 to be conductive. When both transistor 18 and transistor 32 conduct, node 30 is connected to V_{SS}. In response transistor 22 of inverter 20 is strongly conductive and connects V_{DD} directly to node 15. This action overcomes the inability of transistors 16 and 14 to connect V_{DD} to node 15 and fully turns off transistor 16. As a result, no leakage current is permitted to flow through transistors 16, 28, 32 and 18.

Similarly, when the V_{IN}(+) voltage is close to the V_{DD} power supply voltage, transistor 12 is biased on and transistor 14 is biased off. If V_{IN}(−) is the common mode reference voltage, initially transistors 28 and 32 are partially conductive. Node 15 is low enough in voltage to initially make transistor 16 conductive. However transistor 18 may also be somewhat conductive and cause a leakage current to flow through transistors 16, 28, 32 and 18. However, with transistors 16 and 28 being conductive to some degree, node 30 is connected to V_{DD}. A logic high voltage on node 30 causes transistor 24 of inverter 20 to be conductive and directly connect V_{SS} to node 15. The action of inverter 20 thus quickly turns transistor 18 off. Thus the leakage current path is broken as a result of the operation of inverter 20. Inverter 20 has transistors which are not sized as large transistors as the inverter 20 does not need to drive a large signal. As a result, the inverter 20 may be referred to as a weak inverter and is size efficient to implement. Inverter 20 functions to eliminate current leakage paths in amplifier circuit 10. Inverter 20 modifies the voltage at node 15 by either pulling node 15 up to V_{DD} or pulling node 15 down to V_{SS}.

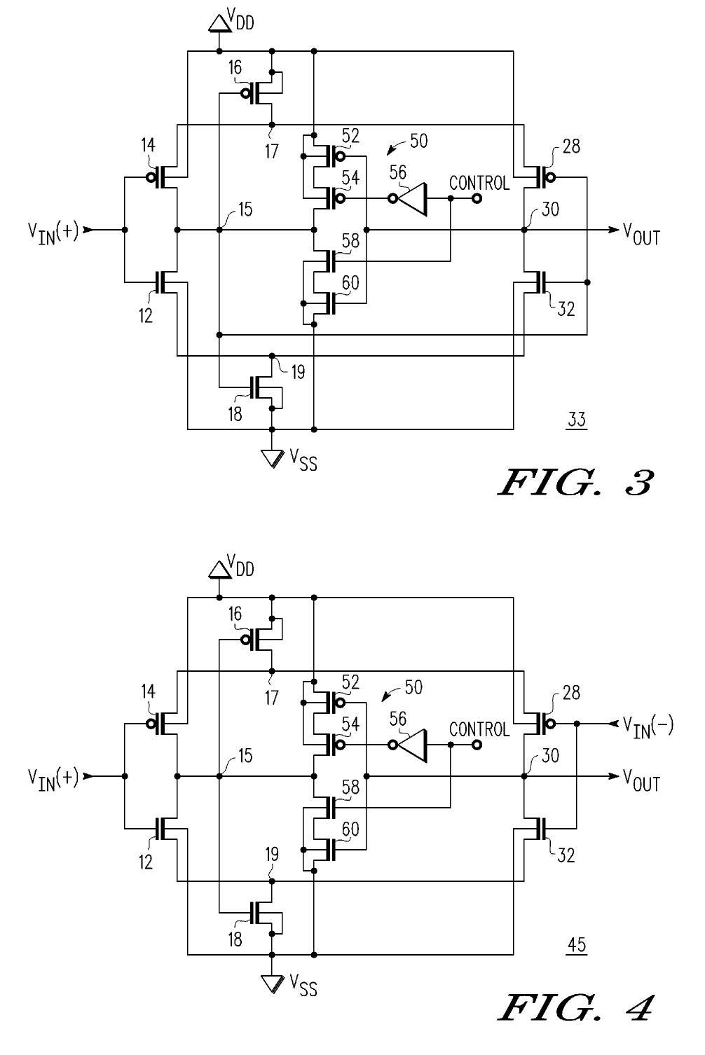

Illustrated in FIG. 2 is an alternative embodiment of an amplifier circuit 21 that has a single input and a single output. For convenience of illustration, reference elements that are common with amplifier circuit 10 of FIG. 1 are identically numbered. The amplifier circuit 21 implements the same transistors and connections with the following exception. The gate of transistor 28 is connected to the gate of transistor 32 and to node 15 rather than providing an input terminal for receiving a second input signal. The only input signal of amplifier circuit 21 is the positive input voltage V_{IN}(+).

In operation, amplifier circuit 21 has a single input signal in the form of voltage V_{IN}(+). The inverter formed by transistors 28 and 32 is driven by the output of the inverter formed by transistors 14 and 12. Inverter 20 again functions to modify the voltage at node 15 to eliminate a current leakage path through transistors 16, 28, 32 and 18 or through transistors 16, 14, 12 and 18. Assume at start-up that the nodes in amplifier circuit 21 are discharged. When V_{IN}(+) has a logic high or V_{DD} value, transistor 12 is conductive and transistor 14 is non-conductive. As a result of node 15 initially being low, transistor 16 and transistor 28 are conductive and couple V_{DD} to node 30. Node 30 therefore biases transistor 22 off and transistor 24 on. Transistor 24 connects V_{SS} directly to node 15 and reinforces the low created by a high V_{IN}(+). This action eliminates a leakage current path through transistors 16, 28, 32 and 18 that would have been caused by a logic indeterminate state existing on node 15 in response to neither of transistors 16 and 18 turning fully off. Amplifier circuit 21 thus is a single-input/single-output amplifier that efficiently conserves power while enabling the use of a V_{DD} voltage value that may not have a large enough magnitude to quickly turn off a transistor due to propagation delays and a small voltage difference between transistor threshold and supply voltage values.

Illustrated in FIG. 3 is another form of an amplifier circuit. An amplifier circuit 33 has a single input and a single output and has elements that are common with those of amplifier circuit 10 and amplifier circuit 21. For convenience of illustration the common elements are numbered the same within amplifier circuit 33. Inverter 20 of FIGS. 1 and 2 is replaced in amplifier circuit 33 with an inverter 50 that is programmable under control of a signal labeled CONTROL. Inverter 50 has a P-channel transistor 52 having a source connected to a substrate thereof and to a voltage terminal for receiving the power supply voltage V_{DD}. Transistor 52 has a gate connected to node 30 for providing the output signal V_{OUT}. A drain of transistor 52 is connected to a source of a P-channel transistor 54. The substrate of transistor 54 is connected to the power supply voltage V_{DD}. The CONTROL signal is connected to an input of an inverter 56. An output of inverter 56 is connected to a gate of a P-channel transistor 54. A drain of transistor 54 is connected to node 15 and to a drain of an N-channel transistor 58. A gate of transistor 58 is connected to the CONTROL signal. A substrate of transistor 58 is connected to the V_{SS} power supply voltage. The source of transistor 58 is connected to a drain of an N-channel transistor 60. A gate of transistor 60 is connected to the gate of transistor 52 at node 30. A substrate of transistor 60 is connected to a source thereof and is connected to the V_{SS} power supply voltage terminal.

In operation, amplifier circuit 33 is a single input/single output amplifier that uses control circuitry to enable and disable the inverter function previously described that biases node 15 to eliminate a leakage current path. When the CONTROL signal is asserted as an active high signal, transistors 54 and 58 are made conductive. The operation of amplifier circuit 33 is otherwise similar to the operation of amplifier circuit 21 of FIG. 2 described above. In other words the inverter 50 functions to directly connect either V_{DD} or V_{SS} to node 15 and make one of transistor 16 or transistor 18 non-conductive when such transistor would not otherwise be non-conductive. If the CONTROL signal is not asserted, the operation of inverter 50 is disabled. In some applications the leakage current may not be significant enough a consideration to enable inverter 50. Depending upon the power needs of an application, the CONTROL signal provides a user with the flexibility to selectively use the inverter 50. When the CONTROL signal is used the operation of amplifier circuit 33 is analogous to the operation of amplifier circuit 21 of FIG. 2. Therefore, a redundant explanation of the circuit operation will not be repeated.

Illustrated in FIG. 4 is yet another form of an amplifier circuit. An amplifier circuit 45 has differential inputs and a single output and has elements that are common with those of amplifier circuit 10, amplifier circuit 21 and amplifier circuit 33. For convenience of illustration the common elements are numbered the same within amplifier circuit 45. In the illustrated form the gate of transistor 28 is connected to a terminal for receiving the input voltage V_{IN}(−). The gate of transistor 28 is also connected to the gate of transistor 32. All other connections associated with amplifier circuit 45 are the same as previously described in connection with amplifier circuit 33.

In operation, amplifier circuit 45 is a differential input/single output amplifier having the inverter 50 used in FIG. 3. Reference elements that are common with those elements in FIGS. 1-3 are given the same number for purposes of comparison and understanding. As in the FIG. 3 embodiment, inverter 50 functions to directly connect either V_{DD} or V_{SS} to node 15 and make one of transistor 16 or transistor 18 non-conductive when such transistor would not otherwise be non-conductive. If the CONTROL signal is not asserted, the operation of inverter 50 is disabled. In some applications the leakage current may not be significant enough a consideration to enable inverter 50. Depending upon the power needs of an application, the CONTROL signal provides a user with the flexibility to selectively use the inverter 50. When the CONTROL signal is used the operation of amplifier circuit 45 is analogous to the operation of amplifier circuit 10 of FIG. 1. Therefore, a redundant explanation of the circuit operation will not be repeated.

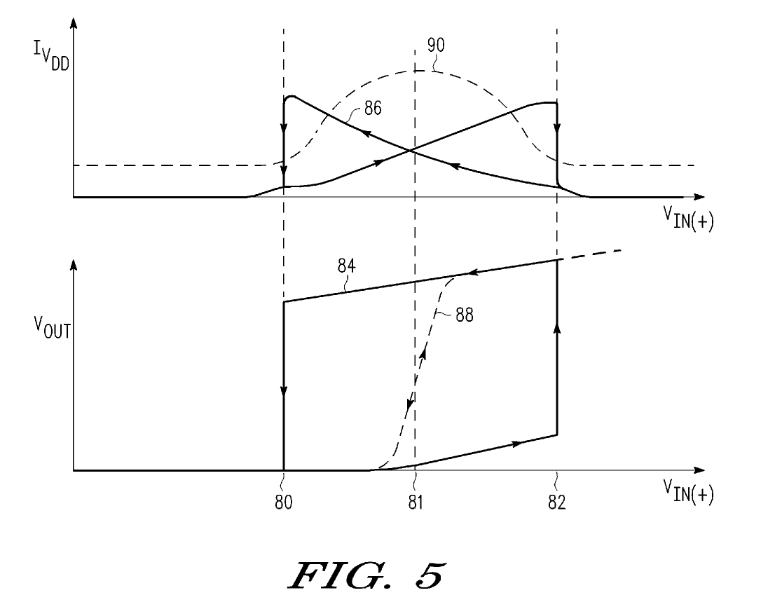

Illustrated in FIG. 5 is a diagram that illustrates the output signal voltage, V_{OUT}, and the current, I_{VDD}, associated with the V_{DD} power supply voltage as a function of the voltage of the input signal V_{IN}(+). Correlated with each other are graphs plotting the value of the amplifier output voltage, V_{OUT} and power supply current as a function of the variation of the input signal V_{IN}(+). The graph is drawn as a solid black line when inverter 50 of FIGS. 3 and 4 is enabled. When inverter 50 is not enabled, a dashed line is indicated. The input voltage is indicated as changing the output voltage by moving between values within a range from a value 80 to a value 82. The input voltage may however assume voltages outside of these values. At a value 81 of the input voltage, a trip point is reached. The value 81 represents a common-mode voltage value that is substantially halfway between the value 80 and the value 82. As the input voltage increases in value past value 82 the output voltage begins to transition from a logic low value to a logic high value as indicated by the solid black line in the direction of the indicated arrow. At value 82, the inverter 50 has connected the V_{SS} power supply terminal to node 15 and caused the output voltage V_{OUT} to simultaneously transition to a logic high voltage. It should be noted that the low-to-high transition point is at value 82. The value of the input voltage is illustrated as decreasing along curve 84. When the value 81 is reached when transitioning to a lower voltage value, there is no immediate transition to zero. The inverter 50 functions between value 81 to value 80 to connect the V_{DD} power supply voltage terminal to node 15 and does so at the value 80. At value 80 the value of the output voltage quickly transitions to zero volts. In contrast, when inverter 50 is not enabled, the low-to-high and high-to-low transition occurs along curve 88 at value 81 which is substantially the common mode voltage. It should be noted that when the inverter 50 is enabled that hysteresis is provided. The value of the input voltage required to implement a low-to-high transition differs from the value of the input voltage required to implement a high-to-low transition. The existence of differing values or transition points is hysteresis and is an advantage by providing noise immunity. Since the transition points are different, if noise exists in the voltage signal there is immunity from making incorrect transitions between high and low values. In contrast, with the curve 88, noise in the input signal may cause transitory errors if the noise causes the input signal to move back and forth around the voltage trip point. It should be noted from FIG. 5 that when inverter 50 is disabled, the transition between low and high output voltage values occurs slightly faster than when inverter 50 is enabled. Thus a tradeoff between speed of operation and power consumption may exist and be a factor in when the CONTROL signal is generated. However, the amount of time required for the input signal to transition between value 81 and either value 82 or value 80 is typically very small for most high frequency signal applications.

FIG. 5 also illustrates the power supply current that is consumed as a function of the value of the input voltage. Both the current when inverter 50 is enabled and when inverter 50 is disabled is shown. The disabled inverter 50 example current is illustrated by a dashed curve. As can be seen from FIG. 5 for the disable inverter example, an amount of current exists for all input voltage values. Also, the peak amount of current consumed when the inverter 50 is disabled is greater than the peak amount of current consumed when the inverter 50 is enabled. When the inverter 50 is enabled and the input voltage increases, the leakage current increases up until value 82. At value 82 the inverter 50 connects node 15 to the V_{SS} power supply voltage terminal and the current immediately falls to zero as the leakage current path is disconnected. Similarly, as the input voltage decreases from a high-to-low value, curve 86 illustrates that the leakage current increases. However, at value 80 the inverter 50 connects node 15 to the V_{DD} power supply voltage terminal and the current immediately falls to zero as the leakage current path is disconnected.

By now it should be appreciated that there has been provided an amplifier circuit that removes leakage current. In one form the leakage current path is selectively removed in response to a CONTROL signal. Depending upon the power consumption issues, selective use of the inverter 20 and inverter 50 in the amplifier is beneficial as a power and speed tradeoff exists. In other applications the amplifier is a differential amplifier having two distinct inputs. The embodiments described herein are useful for many circuit applications, such as dual data rate (DDR) clock and data receivers. The various transistor connections that are illustrated in which connections to the bulk or substrate are detailed function to establish transistor electrical parameters and to assist in avoiding transistor latch-up phenomena. In the illustrated forms the amplifier circuit is implemented with three inverters in which one of the inverters functions to pull up or pull down an output of a first of the three inverters. The pull up or pull down function ensures that the output of the first inverter has a voltage value which is one of the positive power supply or the negative power supply (i.e. typically the ground power supply terminal). It should be understood that all circuitry illustrated and described herein may be implemented either in silicon or another semiconductor material or alternatively by software code representation of silicon or another semiconductor material.

In one form there is herein provided a circuit having a first inverter having an input terminal, an output terminal, a first voltage supply terminal, and a second voltage supply terminal. A second inverter has an input terminal, an output terminal, a first voltage supply terminal, and a second voltage supply terminal. A first transistor has a first current electrode for receiving a first power supply voltage, a control electrode coupled to the output terminal of the first inverter, and a second current electrode coupled to the first voltage supply terminals of both the first and second inverters. A second transistor has a first current electrode coupled to the second voltage supply terminals of both the first and second inverters, a control electrode coupled to the output terminal of the first inverter, and a second current electrode for receiving a second power supply voltage. A third inverter has an input terminal coupled to the output terminal of the second inverter, and an output terminal coupled to the output terminal of the first inverter. In one form the input terminals of the first and second inverters are for receiving a differential input signal. In another form the input terminal of the first inverter is for receiving a logic signal and the input terminal of the second inverter is for receiving a reference voltage. In another form the input terminal of the second inverter is coupled to the output terminal of the first inverter. In another form the third inverter has a third transistor having a first current electrode for receiving the first power supply voltage, a control electrode coupled to the output terminal of the second inverter, and a second current electrode coupled to the output terminal of the first inverter. A fourth transistor has a first current electrode coupled to the second current electrode of the third transistor, a control electrode coupled to the output terminal of the second inverter, and a second current electrode for receiving the second power supply voltage. In another form a third transistor has a first current electrode for receiving the first power supply voltage, a control electrode coupled to the output terminal of the second inverter, and a second current electrode. A fourth transistor has a first current electrode coupled to the second current electrode of the third transistor, a control electrode for receiving a first control signal, and a second current electrode coupled to the output terminal of the first inverter. In another form a fifth transistor has a first current electrode coupled to the second current electrode of the fourth transistor, a control electrode for receiving a second control signal, and a second current electrode. A sixth transistor has a first current electrode coupled to the second current electrode of the fifth transistor, a control electrode coupled to the output terminal of the second inverter, and a second current electrode for receiving the second power supply voltage. In another form the input terminals of the first and second inverters are for receiving a differential input signal. In yet another form the input terminal of the first inverter is for receiving a logic signal and the input terminal of the second inverter is for receiving a reference voltage. In yet another form the first, third, and fourth transistors are of a first conductivity type, and the second fifth and sixth transistors are of a second conductivity type. In yet another form the first power supply voltage is a positive power supply voltage and the second power supply voltage is ground.

In another form there is provided a circuit having a first transistor having a first current electrode, a control electrode, and a second current electrode. A second transistor has a first current electrode coupled to the second current electrode of the first transistor, a control electrode coupled to the control electrode of the first transistor, and a second current electrode. A third transistor has a first current electrode coupled to a first power supply voltage terminal, a control electrode coupled to the second current electrode of the first transistor, and a second current electrode coupled to the first current electrode of the first transistor. A fourth transistor has a first current electrode coupled to the second current electrode of the second transistor, a control electrode coupled to the second current electrode of the first transistor, and a second current electrode coupled to a second power supply voltage terminal. A fifth transistor has a first current electrode coupled to the second current electrode of the third transistor, a control electrode, and a second current electrode. A sixth transistor has a first current electrode coupled to the second current electrode of the fifth transistor, a control electrode coupled to the control electrode of the fifth transistor, and a second current electrode coupled to the first current electrode of the fourth transistor. A seventh transistor has a first current electrode coupled to the first power supply voltage terminal, a control electrode coupled to the second current electrode of the fifth transistor, and a second current electrode coupled to the second current electrode of the first transistor. An eighth transistor has a first current electrode coupled to the second current electrode of the seventh transistor, a control electrode coupled to the control electrode of the seventh transistor, and a second current electrode coupled to the second power supply voltage terminal. In another form the first power supply voltage terminal is for receiving a positive power supply voltage, and the second power supply voltage terminal is coupled to ground. In yet another form the control electrodes of the first, second, fifth, and sixth transistors are for receiving a differential input signal. In yet another form the control electrodes of the first and second transistors are for receiving an input logic signal, and the control electrodes of the fifth and sixth transistors are for receiving a reference voltage. In yet another form the control electrodes of the fifth and sixth transistors are coupled to the second current electrode of the first transistor. In another form a ninth transistor has a first current electrode coupled to the second current electrode of the seventh transistor, a control electrode for receiving a first control signal, and a second current electrode coupled to the second current electrode of the first transistor. A tenth transistor has a first current electrode coupled to the second current electrode of the ninth transistor, a control electrode for receiving a second control signal, and a second current electrode coupled to the first current electrode of the eighth transistor. In another form the control electrodes of the fifth and sixth transistors are coupled to the second current electrode of the first transistor.

In yet another form there is herein provided a circuit having a first P-channel transistor having a first current electrode, a control electrode, and a second current electrode. A first N-channel transistor has a first current electrode coupled to the second current electrode of the first P-channel transistor, a control electrode coupled to the control electrode of the first P-channel transistor, and a second current electrode. A second P-channel transistor has a first current electrode coupled to a first power supply voltage terminal, a control electrode coupled to the second current electrode of the first P-channel transistor, and a second current electrode coupled to the first current electrode of the first P-channel transistor. A second N-channel transistor has a first current electrode coupled to the second current electrode of the first N-channel transistor, a control electrode coupled to the second current electrode of the first P-channel transistor, and a second current electrode coupled to a second power supply voltage terminal. A third P-channel transistor has a first current electrode coupled to the second current electrode of the second P-channel transistor, a control electrode, and a second current electrode. A third N-channel transistor has a first current electrode coupled to the second current electrode of the third P-channel transistor, a control electrode coupled to the control electrode of the third P-channel transistor, and a second current electrode coupled to the first current electrode of the second N-channel transistor. A fourth P-channel transistor has a first current electrode coupled to the first power supply voltage terminal, a control electrode coupled to the second current electrode of the third P-channel transistor, and a second current electrode coupled to the second current electrode of the first P-channel transistor. An fourth N-channel transistor having a first current electrode coupled to the second current electrode of the fourth P-channel transistor, a control electrode coupled to the control electrode of the fourth P-channel transistor, and a second current electrode coupled to the second power supply voltage terminal. In one form the control electrodes of the third P-channel transistor and the third N-channel transistor are coupled to the second current electrode of the first P-channel transistor. In another form there is herein provided a fifth P-channel transistor having a first current electrode coupled to the second current electrode of the fourth P-channel transistor, a control electrode for receiving a first control signal, and a second current electrode coupled to the second current electrode of the first P-channel transistor. A fifth N-channel transistor has a first current electrode coupled to the second current electrode of the fifth P-channel transistor, a control electrode for receiving a second control signal, and a second current electrode coupled to the first current electrode of the fourth N-channel transistor.

In the foregoing specification, the invention has been described with reference to specific embodiments. However, one of ordinary skill in the art appreciates that various modifications and changes can be made without departing from the scope of the present invention as set forth in the claims below. For example, the embodiments described herein may be implemented with any type of transistors. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms a or an, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically.

What is claimed is:

1. A circuit comprising:
a first inverter having an input terminal, an output terminal, a first voltage supply terminal, and a second voltage supply terminal;
a second inverter having an input terminal, an output terminal, a first voltage supply terminal, and a second voltage supply terminal;
a first transistor having a first current electrode for receiving a first power supply voltage, a control electrode coupled to the output terminal of the first inverter, and a second current electrode coupled to the first voltage supply terminals of both the first and second inverters;
a second transistor having a first current electrode coupled to the second voltage supply terminal of both the first and second inverters, a control electrode coupled to the output terminal of the first inverter, and a second current electrode for receiving a second power supply voltage; and
a third inverter having an input terminal coupled to the output terminal of the second inverter, and an output terminal coupled to the output terminal of the first inverter.

2. The circuit of claim 1, wherein the input terminal of each of the first inverter and the second inverter is for receiving a differential input signal.

3. The circuit of claim 1, wherein the input terminal of the first inverter is for receiving a logic signal and the input terminal of the second inverter is for receiving a reference voltage.

4. The circuit of claim 1, wherein the input terminal of the second inverter is coupled to the output terminal of the first inverter.

5. The circuit of claim 1, wherein the third inverter comprises:
a third transistor having a first current electrode for receiving the first power supply voltage, a control electrode coupled to the output terminal of the second inverter, and a second current electrode coupled to the output terminal of the first inverter; and
a fourth transistor having a first current electrode coupled to the second current electrode of the third transistor, a control electrode coupled to the output terminal of the second inverter, and a second current electrode for receiving the second power supply voltage.

6. The circuit of claim 1, further comprising:
a third transistor having a first current electrode for receiving the first power supply voltage, a control electrode coupled to the output terminal of the second inverter, and a second current electrode;
a fourth transistor having a first current electrode coupled to the second current electrode of the third transistor, a control electrode for receiving a first control signal, and a second current electrode coupled to the output terminal of the first inverter;
a fifth transistor having a first current electrode coupled to the second current electrode of the fourth transistor, a control electrode for receiving a second control signal, and a second current electrode; and
a sixth transistor having a first current electrode coupled to the second current electrode of the fifth transistor, a control electrode coupled to the output terminal of the second inverter, and a second current electrode for receiving the second power supply voltage.

7. The circuit of claim 6, wherein the input terminal of the first inverter and the second inverter is for receiving a differential input signal.

8. The circuit of claim 6, wherein the input terminal of the first inverter is for receiving a logic signal and the input terminal of the second inverter is for receiving a reference voltage.

9. The circuit of claim 6, wherein the first, third, and fourth transistors are of a first conductivity type, and the second, fifth, and sixth transistors are of a second conductivity type.

10. The circuit of claim 1, wherein the first power supply voltage is characterized as being a positive power supply voltage and the second power supply voltage is characterized as being ground.

11. A circuit comprising:
a first transistor having a first current electrode, a control electrode, and a second current electrode;
a second transistor having a first current electrode coupled to the second current electrode of the first transistor, a control electrode coupled to the control electrode of the first transistor, and a second current electrode;
a third transistor having a first current electrode coupled to a first power supply voltage terminal, a control electrode coupled to the second current electrode of the first transistor, and a second current electrode coupled to the first current electrode of the first transistor;
a fourth transistor having a first current electrode coupled to the second current electrode of the second transistor, a control electrode coupled to the second current electrode of the first transistor, and a second current electrode coupled to a second power supply voltage terminal;
a fifth transistor having a first current electrode coupled to the second current electrode of the third transistor, a control electrode, and a second current electrode;
a sixth transistor having a first current electrode coupled to the second current electrode of the fifth transistor, a control electrode coupled to the control electrode of the fifth transistor, and a second current electrode coupled to the first current electrode of the fourth transistor;
a seventh transistor having a first current electrode coupled to the first power supply voltage terminal, a control electrode coupled to the second current electrode of the fifth transistor, and a second current electrode coupled to the second current electrode of the first transistor; and
an eighth transistor having a first current electrode coupled to the second current electrode of the seventh transistor, a control electrode coupled to the control electrode of the seventh transistor, and a second current electrode coupled to the second power supply voltage terminal.

12. The circuit of claim 11, wherein the first power supply voltage terminal is for receiving a positive power supply voltage, and the second power supply voltage terminal is coupled to a ground reference.

13. The circuit of claim 11, wherein the control electrode of each of the first, second, fifth, and sixth transistors is for receiving a respective one of a differential input signal.

14. The circuit of claim 11, wherein the control electrode of each of the first transistor and the second transistor is for receiving an input logic signal, and the control electrode of each of the fifth transistor and the sixth transistor is for receiving a reference voltage.

15. The circuit of claim 11, wherein the control electrode of each of the fifth transistor and the sixth transistor is coupled to the second current electrode of the first transistor.

16. The circuit of claim 11, further comprising:
a ninth transistor having a first current electrode coupled to the second current electrode of the seventh transistor, a control electrode for receiving a first control signal, and a second current electrode coupled to the second current electrode of the first transistor; and
a tenth transistor having a first current electrode coupled to the second current electrode of the ninth transistor, a control electrode for receiving a second control signal, and a second current electrode coupled to the first current electrode of the eighth transistor.

17. The circuit of claim 16, wherein the control electrode of each of the fifth transistor and the sixth transistor is coupled to the second current electrode of the first transistor.

18. A circuit comprising:
a first P-channel transistor having a first current electrode, a control electrode, and a second current electrode;
a first N-channel transistor having a first current electrode coupled to the second current electrode of the first P-channel transistor, a control electrode coupled to the control electrode of the first P-channel transistor, and a second current electrode;
a second P-channel transistor having a first current electrode coupled to a first power supply voltage terminal, a control electrode coupled to the second current electrode of the first P-channel transistor, and a second current electrode coupled to the first current electrode of the first P-channel transistor;
a second N-channel transistor having a first current electrode coupled to the second current electrode of the first N-channel transistor, a control electrode coupled to the second current electrode of the first P-channel transistor, and a second current electrode coupled to a second power supply voltage terminal;
a third P-channel transistor having a first current electrode coupled to the second current electrode of the second P-channel transistor, a control electrode, and a second current electrode;
a third N-channel transistor having a first current electrode coupled to the second current electrode of the third P-channel transistor, a control electrode coupled to the control electrode of the third P-channel transistor, and a second current electrode coupled to the first current electrode of the second N-channel transistor;
a fourth P-channel transistor having a first current electrode coupled to the first power supply voltage terminal, a control electrode coupled to the second current electrode of the third P-channel transistor, and a second current electrode coupled to the second current electrode of the first P-channel transistor; and
an fourth N-channel transistor having a first current electrode coupled to the second current electrode of the fourth P-channel transistor, a control electrode coupled to the control electrode of the fourth P-channel transistor, and a second current electrode coupled to the second power supply voltage terminal.

19. The circuit of claim 18, wherein the control electrode of each of the third P-channel transistor and the third N-channel transistor is coupled to the second current electrode of the first P-channel transistor.

20. The circuit of claim 18, further comprising:
a fifth P-channel transistor having a first current electrode coupled to the second current electrode of the fourth P-channel transistor, a control electrode for receiving a first control signal, and a second current electrode coupled to the second current electrode of the first P-channel transistor; and
a fifth N-channel transistor having a first current electrode coupled to the second current electrode of the fifth P-channel transistor, a control electrode for receiving a second control signal, and a second current electrode coupled to the first current electrode of the fourth N-channel transistor.
